(19) United States
(12) Patent Application Publication
(10) Pub. No.: US 2017/0234955 A1
(43) Pub. Date: Aug. 17, 2017

(54) METHOD AND APPARATUS FOR RECONSTRUCTING MAGNETIC RESONANCE IMAGE

(71) Applicant: SAMSUNG ELECTRONICS CO., LTD., Suwon-si (KR)

(72) Inventors: Sang-cheon CHOI, Suwon-si (KR); Dae-ho LEE, Seongnam-si (KR); Jin-young HWANG, Suwon-si (KR)

(73) Assignee: SAMSUNG ELECTRONICS CO., LTD., Suwon-si (KR)

(21) Appl. No.: 15/427,151

(22) Filed: Feb. 8, 2017

(30) Foreign Application Priority Data
Feb. 16, 2016 (KR) 10-2016-0017782

(51) Int. Cl. G01R 33/561; G01R 33/48; G01R 33/56

(52) U.S. Cl. CPC G01R 33/5619; G01R 33/5608; G01R 33/4818

(57) ABSTRACT

A method and an apparatus are provided for reconstructing a plurality of magnetic resonance (MR) images of an object. The method includes synthesizing first MR images of the object to generate a synthesized first MR image, acquiring a k-space data set of the synthesized first MR image, and determining a weighting coefficient representing a relationship between the acquired k-space data set and a k-space data set of a respective one of the first MR images, for each of the first MR images. The method further includes obtaining a multi-band MR image of the object by applying a multi-band radio frequency signal to the object, and reconstructing second MR images from the obtained multi-band MR image, based on the determined weighting coefficient for each of the first MR images.

### CROSS-REFERENCE TO RELATED APPLICATION

This application claims priority from Korean Patent Application No. 10-2016-0017782, filed on Feb. 16, 2016, in the Korean Intellectual Property Office, the disclosure of which is incorporated herein by reference in its entirety.

### BACKGROUND

1. Field

Methods and apparatuses consistent with exemplary embodiments relate to methods of reconstructing magnetic resonance (MR) images and apparatuses for performing the methods.

2. Description of the Related Art

A magnetic resonance imaging (MRI) apparatus uses a magnetic field to capture an image of a target object. The MRI apparatus is widely used in accurate disease diagnosis because stereoscopic images of bones, lumbar discs, joints, nerve ligaments, the heart, etc. can be obtained at desired angles. The main feature of MR imaging is the ability to obtain various image contrasts by adjusting different parameters. Accordingly, for clinical diagnosis, MR images with various contrasts are obtained for the same body area. However, doing a series of scans takes a long time, which may inconvenience a patient. This may cause a patient to voluntarily or involuntarily move, which leads to degradation of image quality and increases in medical fees. Thus, when MR images are acquired, the image acquisition time may be shortened, and the quality of reconstructed images may be improved.

### SUMMARY

Exemplary embodiments may address at least the above problems and/or disadvantages and other disadvantages not described above. Also, the exemplary embodiments are not required to overcome the disadvantages described above, and may not overcome any of the problems described above.

Methods and apparatuses are provided for reconstructing a plurality of magnetic resonance (MR) images from a multi-band MR image by using a relationship between each MR image of the same object and an arbitrarily synthesized MR image.

According to an aspect of an exemplary embodiment, there is provided a method of reconstructing magnetic resonance (MR) images of an object, the method being performed by a magnetic resonance imaging (MRI) apparatus, and the method including synthesizing first MR images of the object to generate a synthesized first MR image, acquiring a k-space data set of the synthesized first MR image, and determining a weighting coefficient representing a relationship between the acquired k-space data set and a k-space data set of a respective one of the first MR images, for each of the first MR images. The method further includes obtaining a multi-band MR image of the object by applying a multi-band radio frequency signal to the object, and reconstructing second MR images from the obtained multi-band MR image, based on the determined weighting coefficient for each of the first MR images.

The method may further include receiving only some of MR signals that are emitted from the object for a predetermined time, obtaining the first MR images, based on the received some of the MR signals, and overlapping at least two of the obtained first MR images in a time domain. The acquiring of the k-space data set of the synthesized first MR image may include acquiring the k-space data set of the synthesized first MR image by performing a Fourier transform on the overlapped at least two of the obtained first MR images.

The first MR images may include a low resolution MR image having a resolution lower than a resolution of the second MR images.

The method may further include overlapping at least two of the first MR images having different contrasts in a time domain, and the acquiring of the k-space data set of the synthesized first MR image may include acquiring the k-space data set of the synthesized first MR image by performing a Fourier transform on the overlapped at least two of the first MR images.

The first MR images may include an MR image that is obtained using an MR imaging protocol that is the same as an MR imaging protocol that is used to obtain the second MR images, and the MR image may have a contrast different than a contrast of the second MR images.

The acquiring of the k-space data set of the synthesized first MR image may include acquiring the k-space data set of the synthesized first MR image via channel coils, and the method may further include constructing a matrix containing pieces of the acquired k-space data of the synthesized first MR image, determining an inverse matrix of the constructed matrix, and acquiring the k-space data set of each of the first MR images via the channel coils. The determining of the weighting coefficient for each of the first MR images may include determining the weighting coefficient for each of the first MR images by multiplying the determined inverse matrix by a matrix containing the acquired k-space data set of the respective one of the first MR images.

The method may further include acquiring a k-space data set of the multi-band MR image, and acquiring a k-space data set of each of the second MR images by applying a respective one of weighting coefficients to the acquired k-space data set of the multi-band MR image. The reconstructing of the second MR images may include reconstructing the second MR images by performing an inverse Fourier transform on the acquired k-space data set of each of the second MR images.

Each of the second MR images may be a single-band MR image including only one MR image of the object.

A non-transitory computer-readable storage medium may store a program to cause a computer to perform the method.

According to another aspect of an exemplary embodiment, there is provided a magnetic resonance imaging (MRI) apparatus for reconstructing magnetic resonance (MR) images of an object, the MRI apparatus including a radio frequency (RF) receiver configured to receive MR signals that are emitted from the object, and an image processor configured to obtain first MR images of the object, based on the received MR signals, synthesize the obtained first MR images to generate a synthesized first MR image, and acquire a k-space data set of the synthesized first MR image. The image processor is further configured to determine a weighting coefficient representing a relationship between the acquired k-space data set and a k-space data set of a respective one of the obtained first MR images, for each of the obtained first MR images, obtain a multi-band MR image of the object by controlling to apply a multi-band radio frequency signal to the object, and reconstruct second MR images from the obtained multi-band MR image, based on the determined weighting coefficient for each of the obtained first MR images.

The RF receiver may be further configured to receive only some of MR signals that are emitted from the object for a predetermined time, and the image processor may be further configured to obtain the first MR images, based on the received some of the MR signals, overlap at least two of the obtained first MR images in a time domain, and acquire the k-space data set of the synthesized first MR image by performing a Fourier transform on the overlapped at least two of the obtained first MR images.

The first MR images may include a low resolution MR image having a resolution lower than a resolution of the second MR images.

The image processor may be further configured to overlap at least two of the first MR images having different contrasts in a time domain, and acquire the k-space data set of the synthesized first MR image by performing a Fourier transform on the overlapped at least two of the first MR images.

The first MR images may include an MR image that is obtained using an MR imaging protocol that is the same as an MR imaging protocol that is used to obtain the second MR images, and the MR image may have a contrast different than a contrast of the second MR images.

The image processor may be further configured to acquire the k-space data set of the synthesized first MR image via channel coils, construct a matrix containing pieces of the acquired k-space data of the synthesized first MR image, determine an inverse matrix of the constructed matrix, acquire the k-space data set of each of the first MR images via the channel coils, and determine the weighting coefficient for each of the first MR images by multiplying the determined inverse matrix by a matrix containing the acquired k-space data set of the respective one of the first MR images.

The image processor may be further configured to acquire a k-space data set of the multi-band MR image, acquire a k-space data set of each of the second MR images by applying a respective one of weighting coefficients to the acquired k-space data set of the multi-band MR image, and reconstruct the second MR images by performing an inverse Fourier transform on the acquired k-space data set of each of the second MR images.

Each of the second MR images may be a single-band MR image including only one MR image of the object.

### BRIEF DESCRIPTION OF THE DRAWINGS

The above and/or other aspects will become apparent and more readily appreciated from the following description of exemplary embodiments, taken in conjunction with the accompanying drawings in which:

FIG. 1 is a schematic diagram of a general magnetic resonance imaging (MRI) apparatus;

FIG. 2 is a block diagram of an MRI apparatus according to an exemplary embodiment;

FIG. 3 is a diagram illustrating a method of reconstructing an MR image, according to an exemplary embodiment;

FIG. 4 is a flowchart of a method of reconstructing an MR image, according to an exemplary embodiment;

FIG. 5 is a diagram illustrating a method of acquiring k-space data by synthesizing a plurality of MR images, according to an exemplary embodiment;

FIG. 6 is a flowchart of a method of acquiring k-space data by synthesizing a plurality of MR images, according to an exemplary embodiment;

FIG. 7 is a diagram illustrating a method of acquiring k-space data by synthesizing a plurality of MR images, according to an exemplary embodiment;

FIG. 8 is a flowchart of a method of acquiring k-space data by synthesizing a plurality of MR images, according to an exemplary embodiment;

FIGS. 9A and 9B are schematic conceptual diagrams illustrating a method of calculating a weighting coefficient, according to an exemplary embodiment;

FIGS. 9C and 9D are schematic diagrams illustrating a matrix equation for calculating a weighting coefficient, according to an exemplary embodiment;

FIG. 10 is a flowchart of a method of calculating a weighting coefficient, according to an exemplary embodiment;

FIG. 11 is a diagram for explaining a method of reconstructing a plurality of single-band MR images from a multi-band MR image, according to an exemplary embodiment; and

FIG. 12 is a flowchart of a method of reconstructing a plurality of single-band MR images from a multi-band MR image, according to an exemplary embodiment.

### DETAILED DESCRIPTION

Exemplary embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the exemplary embodiments. However, it is apparent that the exemplary embodiments can be practiced without those specifically defined matters. Also, well-known functions or constructions may not be described in detail because they would obscure the description with unnecessary detail.

The attached drawings for illustrating exemplary embodiments of the present disclosure are referred to in order to gain a sufficient understanding of the present disclosure, the merits thereof, and the objectives accomplished by the implementation of the present disclosure. In this regard, the exemplary embodiments may have different forms and should not be construed as being limited to the descriptions set forth herein. Rather, these exemplary embodiments are provided so that this disclosure will be thorough and complete and will fully convey the concept of the exemplary embodiments to one of ordinary skill in the art.

Hereinafter, the terms used in the specification will be briefly described, and then the present disclosure will be described in detail.

The terms used in this specification are those general terms currently widely used in the art in consideration of functions regarding the present disclosure, but the terms may vary according to the intention of those of ordinary skill in the art, precedents, or new technology in the art. Also, some terms may be arbitrarily selected by the applicant, and in this case, the meaning of the selected terms will be described in detail in the detailed description of the present specification. Thus, the terms used herein have to be defined based on the meaning of the terms together with the description throughout the specification.

When a part “includes” or “comprises” an element, unless there is a description contrary thereto, the part can further include other elements, not excluding the other elements. Also, the term “unit” in the exemplary embodiments means a software component or hardware component such as a field-programmable gate array (FPGA) or an application-specific integrated circuit (ASIC), and performs a specific function. However, the term “unit” is not limited to software or hardware. The “unit” may be formed to be in an addressable storage medium, or may be formed to operate one or more processors. Thus, for example, the term “unit” may refer to components such as software components, object-oriented software components, class components, and task components, and may include processes, functions, attributes, procedures, subroutines, segments of program code, drivers, firmware, micro codes, circuits, data, a database, data structures, tables, arrays, or variables. A function provided by the components and “units” may be associated with the smaller number of components and “units,” or may be divided into additional components and “units.” Expressions such as “at least one of,” when preceding a list of elements, modify the entire list of elements and do not modify the individual elements of the list.

Throughout the specification, an “image” may denote multi-dimensional data composed of discrete image elements (for example, pixels in a two-dimensional image and voxels in a three-dimensional image). For example, the image may be a medical image of an object captured by an X-ray apparatus, a computed tomography (CT) apparatus, a magnetic resonance imaging (MRI) apparatus, an ultrasound diagnosis apparatus, or another medical imaging apparatus.

Furthermore, in the present specification, an “object” may be a human, an animal, or a part of a human or animal. For example, the object may be an organ (e.g., the liver, the heart, the womb, the brain, a breast, or the abdomen), a blood vessel, or a combination thereof. The object may be a phantom. The phantom means a material having a density, an effective atomic number, and a volume that are approximately the same as those of an organism. For example, the phantom may be a spherical phantom having properties similar to the human body.

Furthermore, in the present specification, a “user” may be, but is not limited to, a medical expert, such as a medical doctor, a nurse, a medical laboratory technologist, or a technician who repairs a medical apparatus.

Furthermore, in the present specification, an “MR image” refers to an image of an object obtained by using the nuclear magnetic resonance principle.

Furthermore, in the present specification, a “pulse sequence” refers to continuity of signals repeatedly applied by an MRI apparatus. The pulse sequence may include a time parameter of a radio frequency (RF) pulse, for example, repetition time (TR) or echo time (TE).

An MRI system is an apparatus for acquiring a sectional image of a part of an object by expressing, in a contrast comparison, a strength of an MR signal with respect to a radio frequency (RF) signal generated in a magnetic field having a specific strength. For example, if an RF signal that only resonates a specific atomic nucleus (for example, a hydrogen atomic nucleus) is emitted for an instant toward the object placed in a strong magnetic field and then such emission stops, an MR signal is emitted from the specific atomic nucleus, and thus the MRI system may receive the MR signal and acquire an MR image. The MR signal denotes an RF signal emitted from the object. An intensity of the MR signal may be determined according to a density of a predetermined atom (for example, hydrogen) of the object, a relaxation time T1, a relaxation time T2, and a flow of blood or the like.

MRI systems include characteristics different from those of other imaging apparatuses. Unlike imaging apparatuses such as CT apparatuses that acquire images according to a direction of detection hardware, MRI systems may acquire 2D images or 3D volume images that are oriented toward an optional point. MRI systems do not expose objects or examiners to radiation, unlike CT apparatuses, X-ray apparatuses, position emission tomography (PET) apparatuses, and single photon emission CT (SPECT) apparatuses, may acquire images having high soft tissue contrast, and may acquire neurological images, intravascular images, musculoskeletal images, and oncologic images that are used to precisely capture abnormal tissues.

Furthermore, in the present specification, the terms “first,” “second,” “1-1,” etc. are only used to distinguish one component, element, object, image, pixel, or patch from another component, element, object, image, pixel, or patch. Thus, these terms are not limited to representing the order or priority among elements or components. Expressions such as “at least one of,” when preceding a list of elements, modify the entire list of elements and do not modify the individual elements of the list.

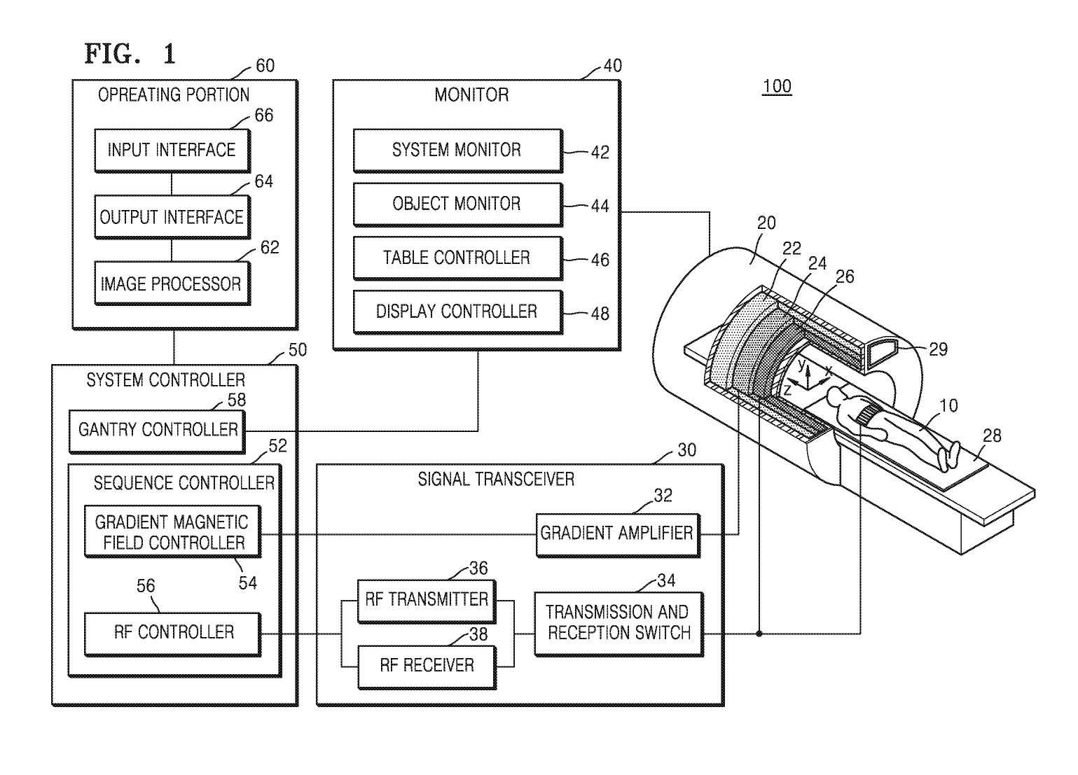

FIG. 1 is a schematic diagram of a general MRI apparatus 100.

Referring to FIG. 1, the general MRI apparatus 100 may include a gantry 20, a signal transceiver 30, a monitor 40, a system controller 50, and an operating portion 60.

The gantry 20 prevents external emission of electromagnetic waves generated by a main magnet 22, a gradient coil 24, and an RF coil 26. A magnetostatic field and a gradient magnetic field are formed in a bore in the gantry 20, and an RF signal is emitted toward an object 10.

The main magnet 22, the gradient coil 24, and the RF coil 26 may be arranged in a predetermined direction of the gantry 20. The predetermined direction may be a coaxial cylinder direction. The object 10 may be disposed on a table 28 that is capable of being inserted into a cylinder along a horizontal axis of the cylinder.

The main magnet 22 generates a magnetostatic field or a static magnetic field for aligning magnetic dipole moments of atomic nuclei of the object 10 in a constant direction. A precise and accurate MR image of the object 10 may be obtained due to a magnetic field generated by the main magnet 22 being strong and uniform.

The gradient coil 24 includes X, Y, and Z coils for generating gradient magnetic fields in X-, Y-, and Z-axis directions crossing each other at right angles. The gradient coil 24 may provide location information of each region of the object 10 by differently inducing resonance frequencies according to the regions of the object 10.

The RF coil 26 may emit an RF signal toward a patient and receive an MR signal emitted from the patient. In detail, the RF coil 26 may transmit, toward atomic nuclei included in the patient and having precessional motion, an RF signal having the same frequency as that of the precessional motion, stop transmitting the RF signal, and then receive an MR signal emitted from the atomic nuclei included in the patient.

For example, to transit an atomic nucleus from a low energy state to a high energy state, the RF coil 26 may generate and apply an electromagnetic wave signal that is an RF signal corresponding to a type of the atomic nucleus, to the object 10. When the electromagnetic wave signal generated by the RF coil 26 is applied to the atomic nucleus, the atomic nucleus may transit from the low energy state to the high energy state. Then, when electromagnetic waves generated by the RF coil 26 disappear, the atomic nucleus to which the electromagnetic waves were applied transits from the high energy state to the low energy state, thereby emitting electromagnetic waves having a Lamor frequency. In other words, when the applying of the electromagnetic wave signal to the atomic nucleus is stopped, an energy level of the atomic nucleus is changed from a high energy level to a low energy level, and thus the atomic nucleus may emit electromagnetic waves having a Lamor frequency. The RF coil 26 may receive electromagnetic wave signals from atomic nuclei included in the object 10.

The RF coil 26 may be realized as one RF transmitting and receiving coil having both a function of generating electromagnetic waves each having an RF that corresponds to a type of an atomic nucleus and a function of receiving electromagnetic waves emitted from an atomic nucleus. Alternatively, the RF coil 26 may be realized as a transmission RF coil having a function of generating electromagnetic waves each having an RF that corresponds to a type of an atomic nucleus, and a reception RF coil having a function of receiving electromagnetic waves emitted from an atomic nucleus.

The RF coil 26 may be fixed to the gantry 20 or may be detachable. When the RF coil 26 is detachable, the RF coil 26 may be an RF coil for a part of the object, such as a head RF coil, a chest RF coil, a leg RF coil, a neck RF coil, a shoulder RF coil, a wrist RF coil, or an ankle RF coil.

The RF coil 26 may communicate with an external apparatus via wires and/or wirelessly, and may also perform dual tune communication according to a communication frequency band.

The RF coil 26 may be a birdcage coil, a surface coil, or a transverse electromagnetic (TEM) coil according to structures.

The RF coil 26 may be a transmission exclusive coil, a reception exclusive coil, or a transmission and reception coil according to methods of transmitting and receiving an RF signal.

The RF coil 26 may be an RF coil having various numbers of channels, such as 16 channels, 32 channels, 72 channels, and 144 channels.

The gantry 20 may further include a display 29 disposed outside the gantry 20 and a display disposed inside the gantry 20. The gantry 20 may provide predetermined information to the user or the object 10 through the display 29 and the display respectively disposed outside and inside the gantry 20.

The signal transceiver 30 may control the gradient magnetic field formed inside the gantry 20, i.e., in the bore, according to a predetermined MR sequence, and control transmission and reception of an RF signal and an MR signal.

The signal transceiver 30 may include a gradient amplifier 32, a transmission and reception switch 34, an RF transmitter 36, and an RF receiver 38.

The gradient amplifier 32 drives the gradient coil 24 included in the gantry 20, and may supply a pulse signal for generating a gradient magnetic field to the gradient coil 24 under the control of a gradient magnetic field controller 54. By controlling the pulse signal supplied from the gradient amplifier 32 to the gradient coil 24, gradient magnetic fields in X-, Y-, and Z-axis directions may be synthesized.

The RF transmitter 36 and the RF receiver 38 may drive the RF coil 26. The RF transmitter 36 may supply an RF pulse in a Lamor frequency to the RF coil 26, and the RF receiver 38 may receive an MR signal received by the RF coil 26.

The transmission and reception switch 34 may adjust transmitting and receiving directions of the RF signal and the MR signal. For example, the transmission and reception switch 34 may emit the RF signal toward the object 10 through the RF coil 26 during a transmission mode, and receive the MR signal from the object 10 through the RF coil 26 during a reception mode. The transmission and reception switch 34 may be controlled by a control signal output by an RF controller 56.

The monitor 40 may monitor or control the gantry 20 or devices mounted on the gantry 20. The monitor 40 may include a system monitor 42, an object monitor 44, a table controller 46, and a display controller 48.

The system monitor 42 may monitor and control a state of the magnetostatic field, a state of the gradient magnetic field, a state of the RF signal, a state of the RF coil 26, a state of the table 28, a state of a device measuring body information of the object 10, a power supply state, a state of a thermal exchanger, and a state of a compressor.

The object monitor 44 monitors a state of the object 10. In detail, the object monitor 44 may include a camera for observing a movement or position of the object 10, a respiration measurer for measuring the respiration of the object 10, an electrocardiogram (ECG) measurer for measuring the electrical activity of the object 10, or a temperature measurer for measuring a temperature of the object 10.

The table controller 46 controls a movement of the table 28 where the object 10 is positioned. The table controller 46 may control the movement of the table 28 according to a sequence control of a sequence controller 50. For example, during moving imaging of the object 10, the table controller 46 may continuously or discontinuously move the table 28 according to the sequence control of the sequence controller 50, and thus the object 10 may be photographed in a field of view (FOV) larger than that of the gantry 20.

The display controller 48 controls the display 29 disposed outside the gantry 20 and the display disposed inside the gantry 20. In detail, the display controller 48 may control the display 29 and the display to be on or off, and may control a screen image to be output on the display 29 and the display. Also, when a speaker is located inside or outside the gantry 20, the display controller 48 may control the speaker to be on or off, or may control sound to be output via the speaker.

The system controller 50 may include a sequence controller 52 for controlling a sequence of signals formed in the gantry 20, and a gantry controller 58 for controlling the gantry 20 and the devices mounted on the gantry 20.

The sequence controller 52 may include the gradient magnetic field controller 54 for controlling the gradient amplifier 32, and the RF controller 56 for controlling the RF transmitter 36, the RF receiver 38, and the transmission and reception switch 34. The sequence controller 52 may control the gradient amplifier 32, the RF transmitter 36, the RF receiver 38, and the transmission and reception switch 34 according to a pulse sequence received from the operating portion 60. Here, the pulse sequence includes all information used to control the gradient amplifier 32, the RF transmitter 36, the RF receiver 38, and the transmission and reception switch 34. For example, the pulse sequence may include information about a strength, an application time, and application timing of a pulse signal applied to the gradient coil 24.

The operating portion 60 may request the system controller 50 to transmit pulse sequence information while controlling an overall operation of the MRI apparatus 100.

The operating portion 60 may include an image processor 62 for receiving and processing the MR signal received by the RF receiver 38, an output interface 64, and an input interface 66.

The image processor 62 may process the MR signal received from the RF receiver 38 to generate MR image data of the object 10.

The image processor 62 receives the MR signal received by the RF receiver 38 and performs any one of various signal processes, such as amplification, frequency transformation, phase detection, low frequency amplification, and filtering, on the received MR signal.

The image processor 62 may arrange digital data in a k space (for example, also referred to as a Fourier space or a frequency space) of a memory, and rearrange the digital data into image data via 2D or 3D Fourier transformation.

The image processor 62 may perform a composition process or difference calculation process on the image data. The composition process may include an addition process on a pixel or a maximum intensity projection (MIP) process. The image processor 62 may store not only the rearranged image data but also image data on which a composition process or a difference calculation process is performed, in a memory or an external server.

The image processor 62 may perform any of the signal processes on the MR signal in parallel. For example, the image processor 62 may perform a signal process on a plurality of MR signals received by a multi-channel RF coil in parallel to rearrange the plurality of MR signals into image data.

The output interface 64 may output image data generated or rearranged by the image processor 62 to the user. The output interface 64 may also output information used for the user to manipulate the MRI apparatus 100, such as a user interface (UI), user information, or object information. The output interface 64 may be a speaker, a printer, a cathode-ray tube (CRT) display, a liquid crystal display (LCD), a plasma display panel (PDP), an organic light-emitting device (OLED) display, a field emission display (FED), a light-emitting diode (LED) display, a vacuum fluorescent display (VFD), a digital light processing (DLP) display, a flat panel display (FPD), a 3-dimensional (3D) display, a transparent display, or any one of other various output devices that are well known to one of ordinary skill in the art.

The user may input object information, parameter information, a scan condition, a pulse sequence, or information about image composition or difference calculation by using the input interface 66. The input interface 66 may be a keyboard, a mouse, a track ball, a voice recognizer, a gesture recognizer, a touch screen, or any one of other various input devices that are well known to one of ordinary skill in the art.

The signal transceiver 30, the monitor 40, the system controller 50, and the operating portion 60 are separate components in FIG. 1, but it will be obvious to one of ordinary skill in the art that respective functions of the signal transceiver 30, the monitor 40, the system controller 50, and the operating portion 60 may be performed by another component. For example, the image processor 62 converts the MR signal received from the RF receiver 38 into a digital signal in FIG. 1, but alternatively, the conversion of the MR signal into the digital signal may be performed by the RF receiver 38 or the RF coil 26.

The gantry 20, the RF coil 26, the signal transceiver 30, the monitor 40, the system controller 50, and the operating portion 60 may be connected to each other by wire or wirelessly, and when they are connected wirelessly, the MRI system may further include an apparatus for synchronizing clock signals therebetween. Communication between the gantry 20, the RF coil 26, the signal transceiver 30, the monitor 40, the system controller 50, and the operating portion 60 may be performed by using a high-speed digital interface, such as low voltage differential signaling (LVDS), asynchronous serial communication, such as a universal asynchronous receiver transmitter (UART), a low-delay network protocol, such as error synchronous serial communication or a controller area network (CAN), optical communication, or any of other various communication methods that are well known to one of ordinary skill in the art.

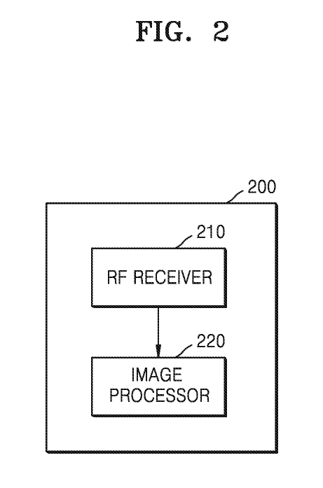

FIG. 2 is a block diagram of an MRI apparatus 200 according to an exemplary embodiment.

Referring to FIG. 2, the MRI apparatus 200 may include an RF receiver 210 and an image processor 220.

The RF receiver 210 may receive an MR signal emitted from an object. Because the RF receiver 210 corresponds to the RF receiver 38 described with reference to FIG. 1, a detailed description thereof will not be repeated below.

The image processor 220 receives the MR signal via the RF receiver 210 and may obtain a plurality of MR images of the object by performing any one of various signal processes, such as amplification, frequency transformation, phase detection, low frequency amplification, and filtering, on the received MR signal.

The image processor 220 may perform the same functions as the image processor 62 described with reference to FIG. 1. Only configuration and function differences from the image processor 62 will be described, and descriptions already provided with respect to the image processor 62 will be omitted.

The image processor 220 may be configured to synthesize a plurality of MR images, perform spatial transformation on the synthesized MR image to acquire a k-space data set, and perform arithmetic operations to calculate a weighting coefficient representing a relationship between the k-space data set corresponding to the synthesized MR image and a k-space data set corresponding to each of the plurality of MR images. Furthermore, the image processor 220 may perform image processing to reconstruct a plurality of MR images from a multi-band MR image by using a calculated weighting coefficient. For example, the image processor 220 may include any one or any combination of a central processing unit (CPU), a microprocessor, a graphics processing unit, random-access memory (RAM), and read-only memory (ROM). According to an exemplary embodiment, the image processor 220 may be implemented as an application processor (AP). In an exemplary embodiment, the image processor 220 may be implemented using a hardware component such as a field-programmable gate array (FPGA) or an application-specific integrated circuit (ASIC). However, exemplary embodiments are not limited thereto, and the image processor 220 may include components such as software components, object-oriented software components, class components, and task components, processes, functions, attributes, procedures, subroutines, segments of program code, drivers, firmware, micro codes, circuits, data, a database, data structures, tables, arrays, or variables.

According to an exemplary embodiment, the image processor 220 may synthesize a plurality of MR images of the object and acquire a k-space data set corresponding to a synthesized MR image. The image processor 220 may receive only some MR signals emitted from the object for a predetermined time and obtain a reference image based on the received MR signals. In another exemplary embodiment, the image processor 220 may perform spatial transformation on a plurality of MR images having different contrasts to acquire a k-space data set. For example, the image processor 220 may synthesize at least two of a plurality of MR images having different contrasts by overlapping the at least two MR images in the time domain and perform a Fourier transform on the synthesized MR image to thereby acquire a k-space data set corresponding to the synthesized MR image.

According to an exemplary embodiment, the image processor 220 may calculate a weighting coefficient representing a relationship between a k-space data set corresponding to a synthesized MR image and a k-space data set corresponding to each MR image. The image processor 220 may acquire a k-space data set corresponding to the synthesized MR image by using a plurality of channel coils and construct a matrix containing k-space data respectively acquired by the plurality of channel coils. The image processor 220 may calculate an inverse matrix of the matrix containing the k-space data respectively acquired via the plurality of channel coils and multiply the inverse matrix by a matrix containing a k-space data set corresponding to each of the plurality of MR images to thereby calculate a weighting coefficient for each of the plurality of MR images.

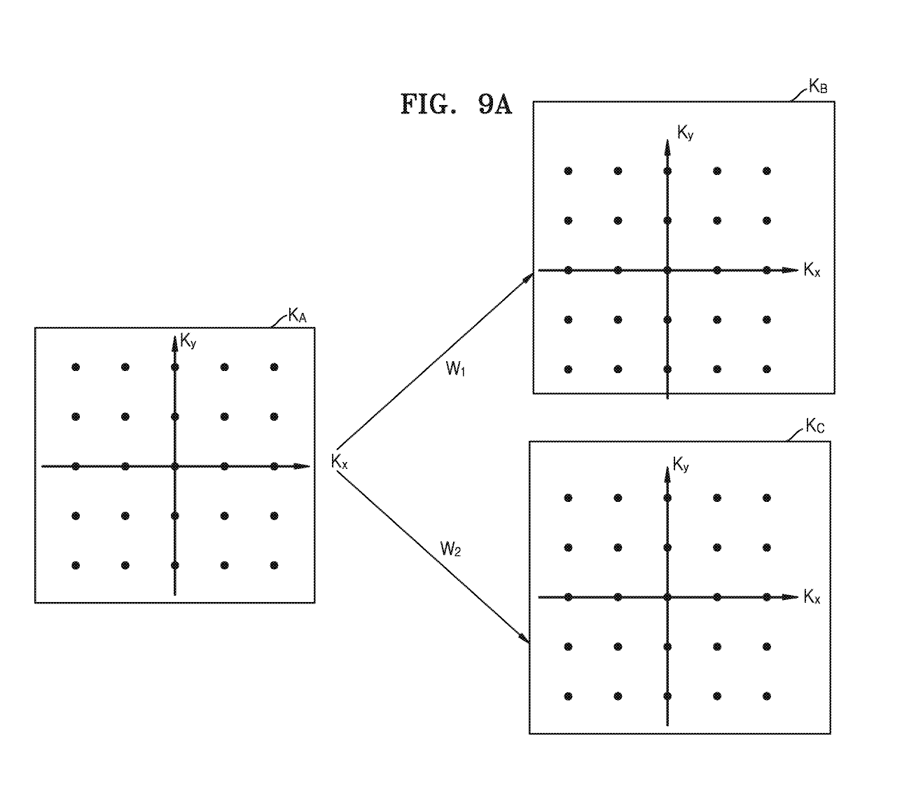

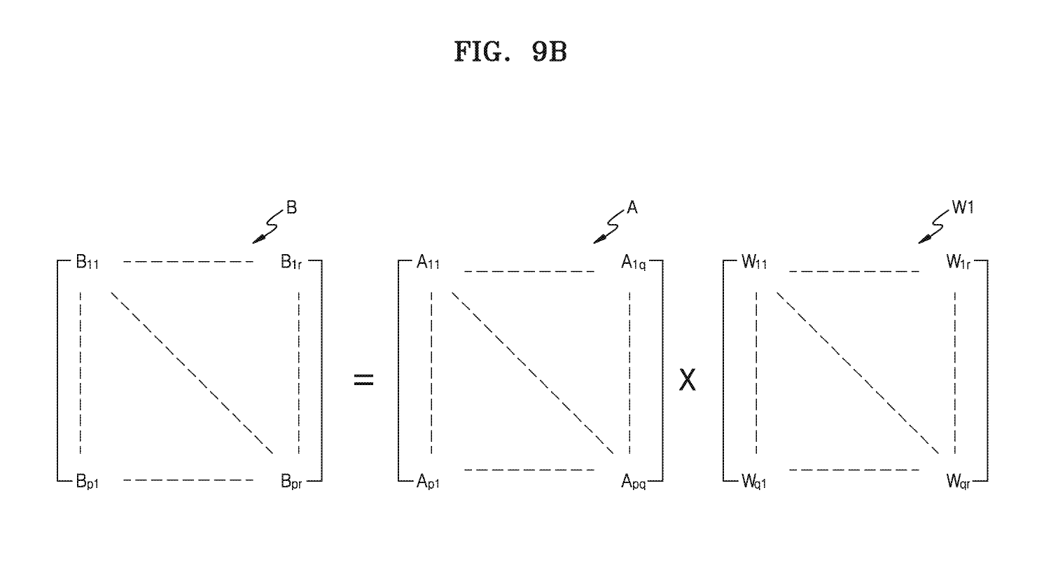

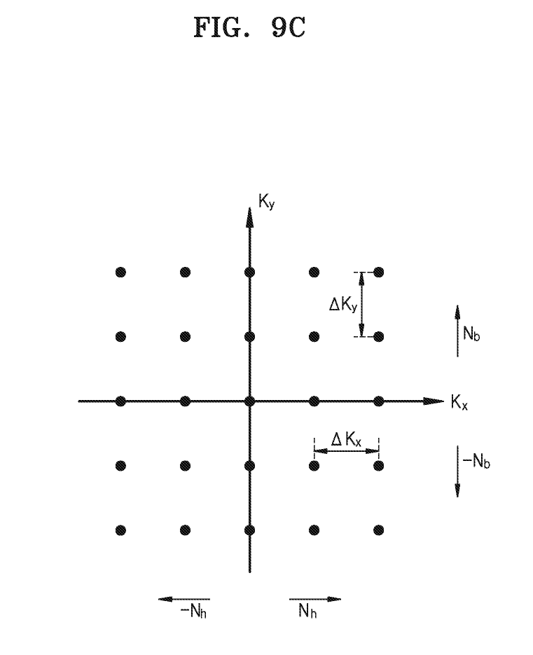

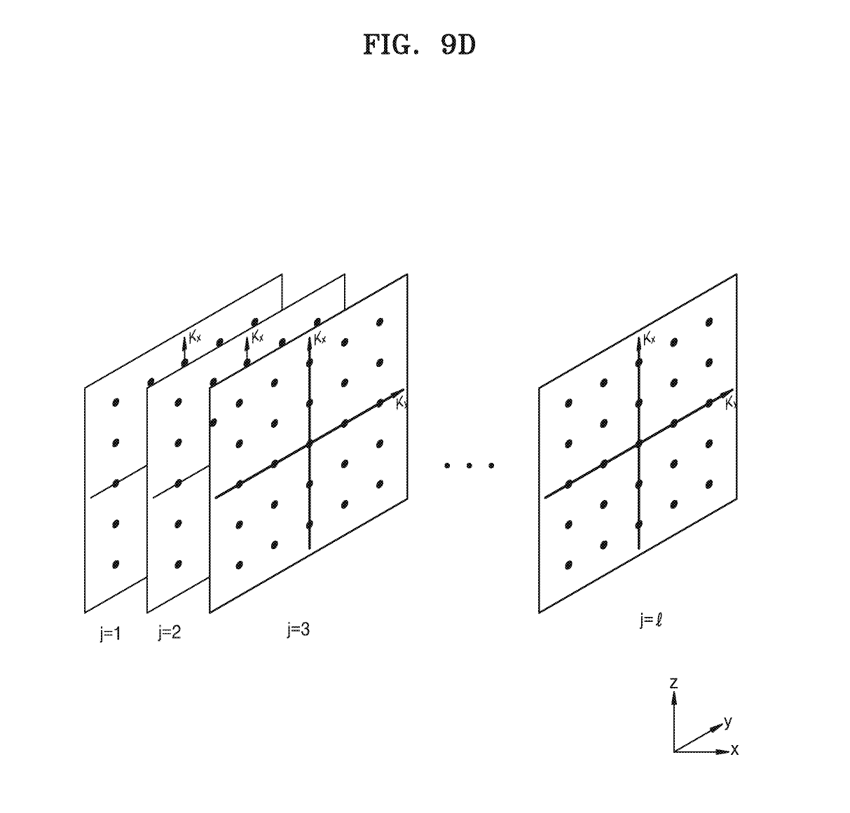

A weighting coefficient is a matrix representing a relationship between a k-space data set corresponding to a synthesized image of at least two MR images and a k-space data set corresponding to each of the at least two MR images before they are synthesized. Calculation of a weighting coefficient will be described in detail below with reference to FIGS. 9A through 9C.

According to an exemplary embodiment, the MRI apparatus 200 may further include a memory. Weighting coefficients calculated by the image processor 220 may be stored in the memory. For example, the memory may include any one or any combination of a volatile memory (e.g., dynamic RAM (DRAM), static RAM (SRAM), synchronous dynamic RAM (SDRAM), etc.), a non-volatile memory (e.g., one time programmable ROM (OTPROM), programmable ROM (PROM), erasable and programmable ROM (EPROM), electrically erasable and programmable ROM (EEPROM), mask ROM, flash ROM, etc.), a hard disk drive (HDD), and a solid state drive (SSD).

The image processor 220 may obtain a multi-band MR image of the object and reconstruct a plurality of single-band MR images from the multi-band MR image by using a weighting coefficient. The multi-band MR image is an image obtained by acquiring at least two 2D MR imaging slices of the object at one time, and the single-band MR image is an image containing only one MR image of the object. Because a multi-band MR image described herein is fully understood and appreciated by those of ordinary skill in the art, a detailed description thereof will be omitted.

In an exemplary embodiment, the image processor 220 may acquire a k-space data set corresponding to a multi-band MR image and reconstruct a plurality of single-band MR images from the multi-band k-space MR image by applying a weighting coefficient to the acquired k-space data set.

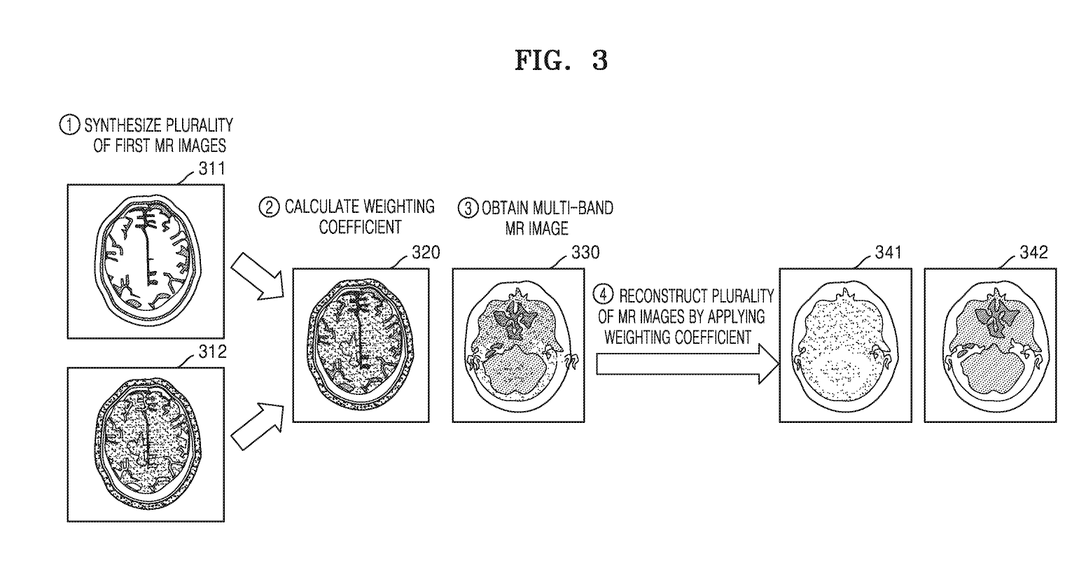

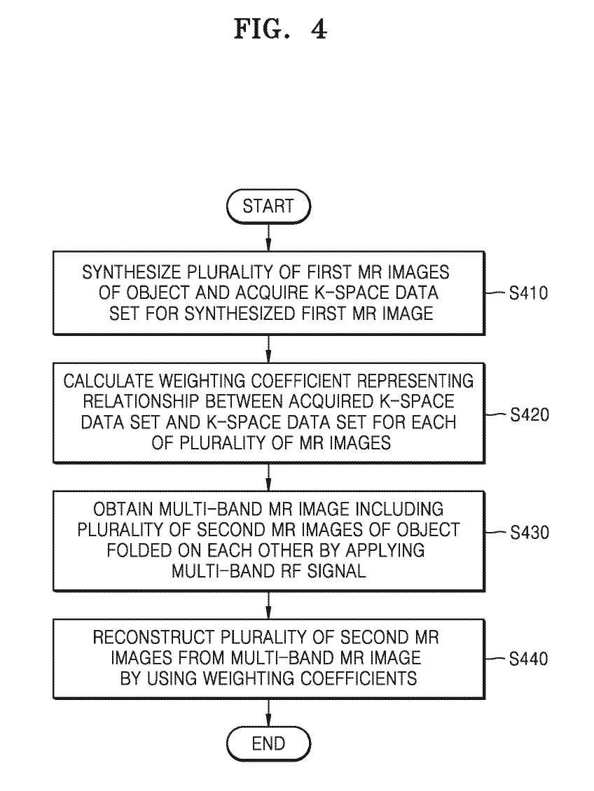

FIG. 3 is a diagram illustrating a method of reconstructing an MR image, according to an exemplary embodiment, and FIG. 4 is a flowchart of a method of reconstructing an MR image, according to an exemplary embodiment.

Referring to FIGS. 3 and 4, an MRI apparatus synthesizes a plurality of first MR images 1-1 311 and 1-2 312 of an object and acquires a k-space data set for a synthesized first MR image (S410). According to an exemplary embodiment, the MRI apparatus may emit RF signals toward the object and receive MR signals emitted from the object via a plurality of channel coils. The MRI apparatus may then arrange the received MR signals in a k-space, sample k-space data, and perform an inverse Fourier transform on the k-space data to thereby obtain the plurality of first MR images 1-1 311 and 1-2 312.

According to an exemplary embodiment, the plurality of first MR images 1-1 311 and 1-2 312 may be low-resolution images obtained by receiving only some of all MR signals emitted from the object for a predetermined short period of time. For example, the plurality of first MR images 1-1 311 and 1-2 312 may be MR images obtained based on a gradient echo (GRE) sequence. According to another exemplary embodiment, the plurality of first MR images 1-1 311 and 1-2 312 may be MR images having different contrasts, which are obtained based on all the MR signals emitted from the object.

The MRI apparatus may obtain a synthesized MR image 320 by synthesizing at least two of the plurality of first MR images 1-1 311 and 1-2 312. In an exemplary embodiment, the MRI apparatus may generate the synthesized MR image 320 by overlapping the plurality of first MR images 1-1 311 and 1-2 312 in the time domain.

The MRI apparatus may perform a Fourier transform on the synthesized MR image 320 to acquire a k-space data set corresponding to the synthesized MR image 320. Because k-space data has linear properties, when the plurality of first MR images 1-1 311 and 1-2 312 are overlapped in the time domain, k-space data sets respectively corresponding to the first MR images 1-1 311 and 1-2 312 may also be overlapped accordingly.

The MRI apparatus calculates a weighting coefficient representing a relationship between the acquired k-space data set and a k-space data set for each of the plurality of first MR images 1-1 311 and 1-2 312 (S420). According to an exemplary embodiment, a weighting coefficient may represent a relationship between the k-space data set corresponding to the synthesized MR image 320 generated in operation S410 and the k-space data set corresponding to the first MR image 1-1 311. Similarly, a weighting coefficient may represent a relationship between the k-space data set corresponding to the synthesized MR image 320 and the k-space data set corresponding to the first MR image 1-2 312. According to an exemplary embodiment, a weighting coefficient may be represented in a matrix including a set of k-space data received via a plurality of channel coils. The MRI apparatus may calculate a first weighting coefficient representing a relationship between the first MR image 1-1 311 and the synthesized MR image 320 by multiplying an inverse of a matrix containing the k-space data set corresponding to the synthesized MR image 320 by a matrix containing the k-space data set corresponding to the first MR image 1-1 311. The MRI apparatus may calculate a second weighting coefficient representing a relationship between the synthesized MR image 320 and the first MR image 1-2 312 in the same way as described above.

The MRI apparatus obtains a multi-band MR image 330 including a plurality of second MR images 2-1 341 and 2-2 342 of the object overlapped or folded on each other by applying a multi-band RF signal to the object (S430). According to an exemplary embodiment, the MRI apparatus may obtain the multi-band MR image 330 including at least two MR slices of the object overlapped on each other. In an exemplary embodiment, the multi-band MR image 330 may be obtained using partially parallel acquisition in which a plurality of MR signals received via a plurality of RF channel coils are reconstructed into image data by performing signal processing operations on the plurality of MR signals in parallel.

The MRI apparatus reconstructs the plurality of second MR images 2-1 341 and 2-2 342 from the multi-band MR image 330 by using or applying weighting coefficients (S440).

The MRI apparatus may acquire a k-space data set for the multi-band MR image 330. The MRI apparatus may acquire the k-space data set for the multi-band MR image 330 by performing a Fourier transform on the multi-band MR image 330.

Although FIG. 3 shows that the plurality of first MR images 1-1 311 and 1-2 312 are two MR images, exemplary embodiments are not limited thereto, and they may be three or more MR images. Similarly, although the number of second MR images 2-1 341 and 2-2 342 reconstructed from the multi-band MR image 330 is two (2), exemplary embodiments are not limited thereto. The number of second MR images 2-1 341 and 2-2 342 may vary depending on the number of MR images overlapped to generate the synthesized MR image 320, i.e., the number of first MR images 1-1 311 and 1-2 312. For example, if the synthesized MR image 320 is generated by overlapping three MR images in the time domain, the reconstructed plurality of second MR images 2-1 341 and 2-2 342 may include three single-band MR images.

The MRI apparatus may acquire k-space data sets respectively corresponding to the plurality of second MR images 2-1 341 and 2-2 342 by applying weighting coefficients to a k-space data set for the obtained multi-band MR image 330. According to an exemplary embodiment, the MRI apparatus may acquire a k-space data set corresponding to the second MR image 2-1 341 by multiplying a matrix containing the k-space data set corresponding to the multi-band MR image 330 by a first weighting coefficient matrix and reconstruct the second MR image 2-1 341 by performing an inverse Fourier transform on the acquired k-space data set. In the same manner, the MRI apparatus may acquire a k-space data set corresponding to the second MR image 2-2 342 by multiplying the matrix containing the k-space data set corresponding to the multi-band MR image 330 by a second weighting coefficient matrix and reconstruct the second MR image 2-2 342 by performing an inverse Fourier transform on the acquired k-space data set. The second MR images 2-1 341 and 2-2 342 may be single-band MR images, each including only a single MR image of the object.

Shortening the scan time is an issue in acquisition of an MR image of the object via an MRI apparatus. A long scan time may inconvenience a patient, and cause the patient to move, which leads to degradation of image quality and increases in medical fees. According to the exemplary embodiments described with reference to FIGS. 3 and 4, the MRI apparatus may obtain a multi-band MR image and reconstruct a plurality of single-band MR images from the multi-band MR image by using a weighting coefficient instead of a separate coil sensitivity map. Thus, the total scan time may be reduced and the quality of reconstructed MR images may be improved.

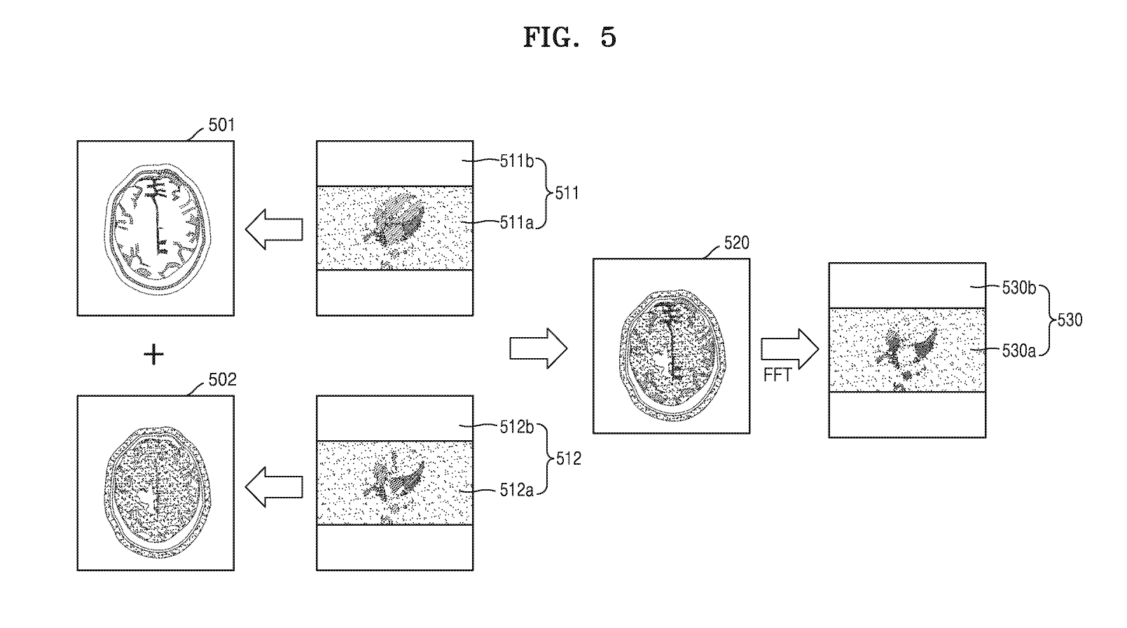

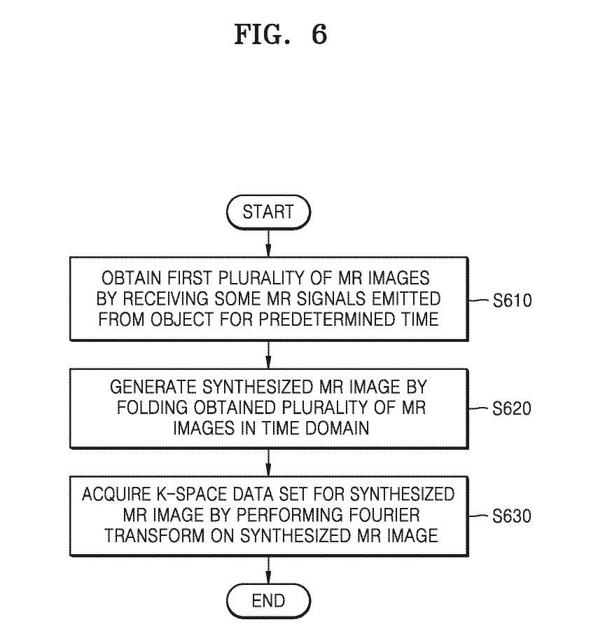

FIG. 5 is a diagram illustrating a method of acquiring a k-space data set 530 by synthesizing a plurality of reference MR images 501 and 502, according to an exemplary embodiment, and FIG. 6 is a flowchart of a method of acquiring the k-space data set 530 by synthesizing the plurality of reference MR images 501 and 502, according to an exemplary embodiment.

Referring to FIGS. 5 and 6, an MRI apparatus receives only some MR signals emitted from an object for a predetermined time and obtains a plurality of reference MR images, i.e., first and second reference MR images 501 and 502 (S610). The first and second reference MR images 501 and 502 shown in FIG. 5 may be generated based on first and second k-space data sets 511 and 512, respectively. The first k-space data set 511 may include acquired k-space data 511a produced by acquiring only some MR signals during a short period of time among total MR signals that are emitted from the object. The first k-space data set 511 may include unacquired k-space data 511b missing in a full k-space data set to be used to completely reconstruct the first reference MR image 501. Similarly, the second k-space data set 512 may include acquired k-space data 512a produced by acquiring only some MR signals among total MR signals that are emitted from the object and unacquired k-space data 512b.

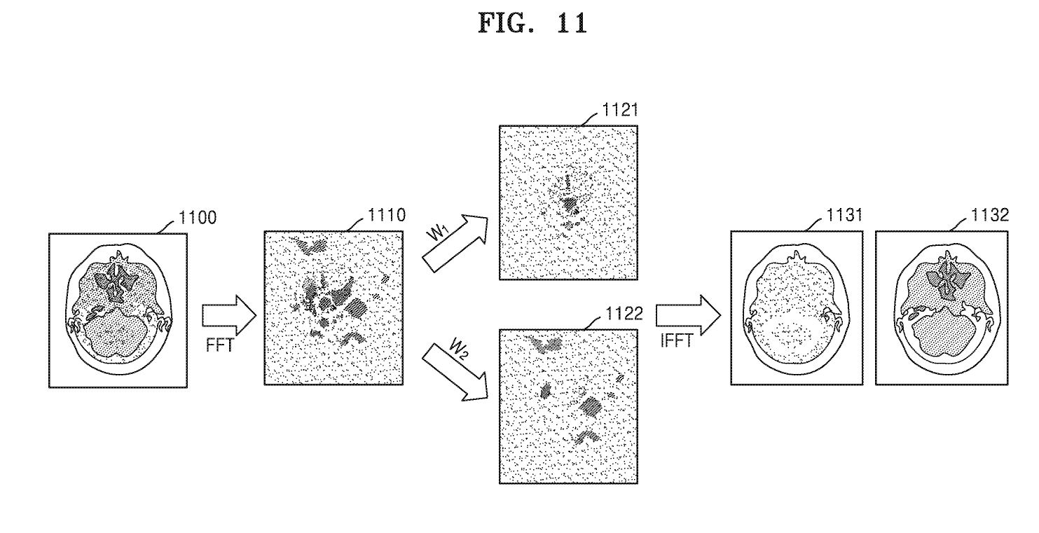

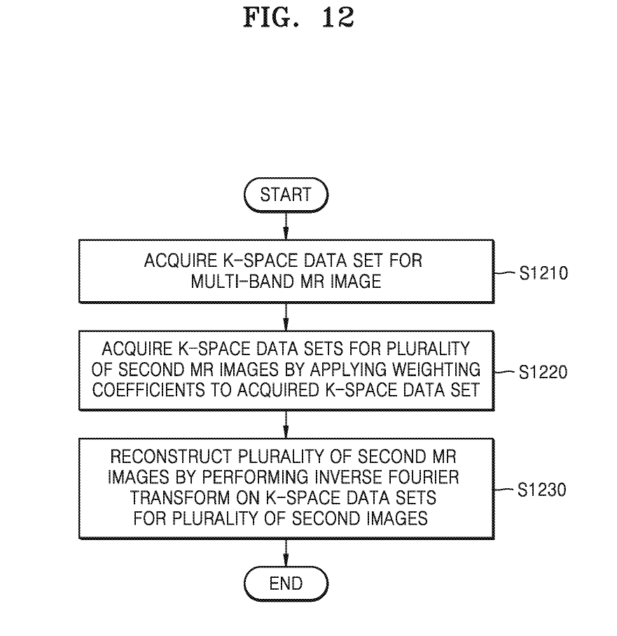

The first and second reference MR images 501 and 502 may be low-resolution MR images obtained based on a portion of the entire k-space data set to be used to reconstruct a complete MR image, i.e., pieces of k-space data that are acquired for a predetermined short period of time, e.g., in less than several seconds. According to an exemplary embodiment, the first and second reference MR images 501 and 502 may be reference images for generating a synthesized MR image 520 and calculating a weighting coefficient used during a main scan performed on the object or an MR image reconstruction process (See FIGS. 11 and 12). In an exemplary embodiment, the first and second reference MR images 501 and 502 may be MR images obtained based on a GRE sequence.

The MRI apparatus generates a synthesized MR image 520 by overlapping or folding the obtained first and second reference MR images 501 and 502 in the time domain (S620). According to an exemplary embodiment, the MRI apparatus may generate the synthesized MR image 520 by overlapping the first and second reference MR images 501 and 502 in the time domain.

The MRI apparatus acquires a k-space data set 530 for the synthesized MR image 520 by performing a Fourier transform on the synthesized MR image 520 (S630). The k-space data set 530 may include acquired k-space data 530a and unacquired k-space data 530b.

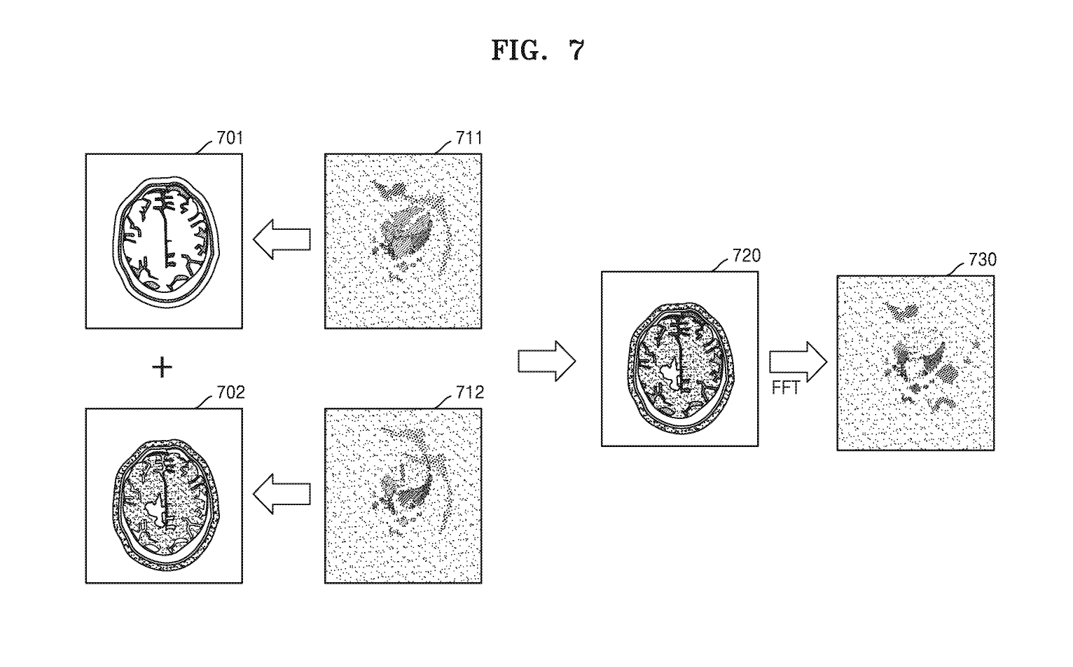

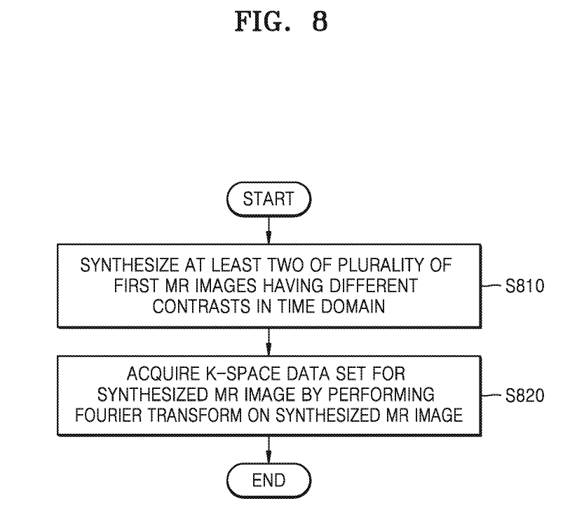

FIG. 7 is a diagram illustrating a method of acquiring a k-space data set 730 by synthesizing a plurality of MR images 710 and 702, according to an exemplary embodiment, and FIG. 8 is a flowchart of a method of acquiring the k-space data set 730 by synthesizing the plurality of MR images 701 and 702, according to an exemplary embodiment.

Referring to FIGS. 7 and 8, an MRI apparatus synthesizes at least two of a plurality of first MR images 1-1 701 and 1-2 702 having different contrasts in the time domain (S810). According to an exemplary embodiment, the plurality of first MR images 1-1 701 and 1-2 702 may be obtained for the same object by same MR imaging protocol as for a plurality of second MR images (1131 and 1132 of FIG. 11) to be reconstructed later. Each of the first MR images 1-1 701 and 1-2 702 may be an MR image including all pieces of information acquired by receiving all MR signals that are applied via a plurality of RF channel coils and emitted from an object. In an exemplary embodiment, the first MR images 1-1 701 and 1-2 702 may respectively be generated based on first and second k-space data sets 711 and 712 of the object.

According to an exemplary embodiment, the first MR images 1-1 701 and 1-2 702 may have different contrasts. For example, the first MR image 1-1 701 may be a T2-weighted (T2W) image, and the first MR image 1-2 702 may be a T1-weighted (T1W) image. However, exemplary embodiments are not limited thereto, and the first MR images 1-1 701 and 1-2 702 may be MR images having different contrasts and may include any one or any combination of T1 W, T1-weighted contrast-enhanced (T1CE), T2 W, fluid-attenuated inversion-recovery (FLAIR), diffusion-weighted (DWI), and proton density weighted (PDW) images.

The MRI apparatus acquires a k-space data set 730 for a synthesized MR image 720 by performing a Fourier transform on the synthesized MR image 720 (S820).

FIGS. 9A and 9B are schematic conceptual diagrams illustrating a method of calculating a weighting coefficient, according to an exemplary embodiment. In FIGS. 9A and 9B, Kₓ and K_{y} denote coordinates in a k-space, i.e., a frequency space, and each point on the k-space may represent a k-space data value at each frequency coordinate.

Referring to FIG. 9A, when weighting coefficients W₁ and W₂ are applied to a synthesized k-space data set K_{A} that is acquired by performing a Fourier transform after overlapping a plurality of MR images in the time domain, the synthesized k-space data set K_{A} may be separated into a plurality of k-space data sets, i.e., first and second k-space data sets K_{B} and K_{C} respectively corresponding to the plurality of MR images. Because the synthesized k-space data set K_{A} is acquired by performing a Fourier transform on a synthesized MR image generated in the time domain, the synthesized k-space data set K_{A} may be separated into the first and second k-space data sets K_{B} and K_{C} due to linearity of the Fourier transform.

According to an exemplary embodiment, the synthesized k-space set K_{A} may be represented by a matrix containing k-space data values in the Kₓ and K_{y} directions. Similarly, the first and second k-space data sets K_{B} and K_{C} may be each represented by a matrix containing k-space data values in the Kx and Ky directions.

Referring to FIG. 9B, a first k-space data matrix B may be calculated as the product of a synthesized k-space data matrix A and a first weighting coefficient matrix W₁. In other words, the first k-space data matrix B may be defined simply by Equation (1) below:

B=A×w₁ (1)

In FIG. 9B, p, q, and r denote the number of rows and columns in the first k-space data matrix B and the synthesized k-space data matrix A and are examples for explaining a multiplication of matrices. Thus, p, q, and r do not represent parameters of the first k-space data matrix B and the synthesized k-space data matrix A.

In the same manner, a second k-space data matrix C may be calculated as the product of the synthesized k-space data matrix A and a second weighting coefficient matrix W₂, as defined by Equation (2) below:

C=A×w₂ (2)

FIGS. 9C and 9D are schematic diagrams illustrating a matrix equation for calculating a weighting coefficient, according to an exemplary embodiment.

$$\frac{2 π}{FOVx} \frac{2 π}{FOVy}$$

Referring to FIG. 9C, a weighting coefficient matrix may contain k-space data values in a plurality of Kₓ and K_{y} directions. Although FIG. 9C shows that the entire field of view (FOV) of the weighting coefficient matrix is 5×5, exemplary embodiments are not limited thereto. In the weighting coefficient matrix, ΔKₓ may be calculated by

$$\frac{2 π}{FOVx} ,$$

and ΔK_{y} may be calculated by

$$\frac{2 π}{FOVy} .$$

The weighting coefficient matrix may include the number +Nₕ of kernels in the positive Kₓ direction and the number −Nₕ of kernels in the negative Kₓ direction. Furthermore, the weighting coefficient matrix may include the number +N_{b} of kernels in the positive K_{y} direction and the number −N_{b} of kernels in the negative K_{y} direction.

Referring to FIG. 9D, the weighting coefficient matrix may consist of matrices obtained for a plurality of RF channel coils. According to an exemplary embodiment, an MR image may be obtained based on partially parallel image signals acquired via a plurality of RF channel coils, a gradient coil, and a plurality of RF receive coils included in an MRI apparatus, and thus, the weighting coefficient matrix may be a 3D matrix for MR signals acquired via the plurality of RF channel coils. In FIG. 9D, I denotes a coil number that identifies the plurality of RF channel coils.

According to an exemplary embodiment, a weighting coefficient matrix may be obtained by using Equation (3) below:

$${S}_{j} ( {k}_{y} + r Δ {k}_{y} , {k}_{x} ) = {\sum }_{l = 1}^{L} {\sum }_{b = - {N}_{b}}^{Na} {\sum }_{h = - {H}_{2}}^{Hr} {W}_{j , k} ( I , b , h ) \times {S}_{l} ( {k}_{y} + b R Δ {k}_{y} , {k}_{x} + h Δ {k}_{x} ) \qquad ( 3 )$$

In Equation (3), Sⱼ is a matrix with k-space data values of a single-band MR image, i.e., the first or second k-space data matrix B or C shown in FIG. 9B, and W_{j,r} is a weighting coefficient matrix. For example, if Sⱼ represents the first k-space data matrix B, W_{j,r} may represent the first weighting coefficient matrix W₁. If Sj is the second k-space data matrix C, Wj,r may represent the second weighting coefficient matrix W₂. In Equation (3), I is the number of a plurality of RF channel coils, b and h are kernels in the K_{y} and Kₓ directions, respectively, Nb and Nh are the number of kernels in the K_{y} and Kₓ directions, respectively, and r is a sampling factor (r=R−1). ΔKₓ may be calculated by

$$\frac{2 π}{FOVx}$$

and ΔK_{y} may be calculated by

$$\frac{2 π}{FOVy}$$

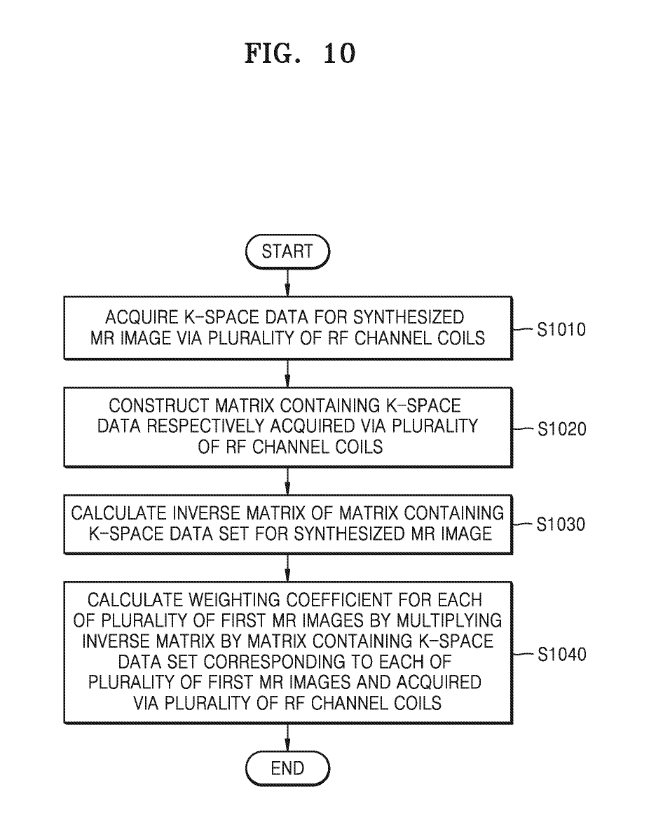

FIG. 10 is a flowchart of a method of calculating a weighting coefficient according to an exemplary embodiment.

Referring to FIG. 10, an MRI apparatus acquires a k-space data set for a synthesized MR image via a plurality of RF channel coils (S1010). According to an exemplary embodiment, the MRI apparatus may emit RF signals towards an object and receive MR signals emitted from the object via a plurality of RF channel coils. The MRI apparatus may arrange the received MR signals in a k-space and sample a k-space data set.

The MRI apparatus constructs a matrix containing k-space data respectively acquired via the plurality of RF channel coils (S1020). Referring to FIG. 9D, the MRI apparatus may construct a 3D matrix with k-space data values respectively acquired for the number j of RF channel coils (j=1, 2, . . . , l).

The MRI apparatus calculates an inverse matrix of a matrix containing the k-space data set for the synthesized MR image (S1030). Referring to the exemplary embodiment and Equation (1) (B=A×W₁) described with reference to FIG. 9B, the first k-space data matrix B may be calculated as the product of the synthesized k-space data matrix A and the first weighting coefficient matrix W₁. By calculating an inverse matrix of the synthesized k-space data matrix A, the first weighting coefficient matrix W₁ may be obtained. In the same manner, referring to Equation (2) (C=A×W₂), the second k-space data matrix C may be calculated as the product of the synthesized k-space data matrix A and the second weighting coefficient matrix W₂. By calculating the inverse matrix of the synthesized k-space data matrix A, the second weighting coefficient matrix W₂ may be obtained.

The MRI apparatus calculates a weighting coefficient for each of a plurality of first MR images by multiplying the calculated inverse matrix by a matrix containing a k-space data set corresponding to each of the plurality of first MR images and acquired via the plurality of RF channel coils (S1040). Referring to FIG. 9B, the MRI apparatus may obtain the first weighting coefficient matrix W₁ by multiplying the inverse matrix of the synthesized k-space data matrix A by the first k-space data matrix B. In other words, the first weighting coefficient matrix W₁ may be obtained by using Equation (4) below:

w₁=A⁻¹×B (4)

Similarly, as defined by Equation (5), the second weighting coefficient matrix W₂ may be obtained by multiplying the inverse matrix of the synthesized k-space data matrix A by the second k-space data matrix C:

w₂=A⁻¹×C (5)

FIG. 11 is a diagram illustrating a method of reconstructing a plurality of single-band MR images 1131 and 1132 from a multi-band MR image 1100, according to an exemplary embodiment, and FIG. 12 is a flowchart of a method of reconstructing the plurality of single-band MR images 1131 and 1132 from a multi-band MR image 1100, according to an exemplary embodiment.

Referring to FIGS. 11 and 12, an MRI apparatus acquires a k-space data set corresponding to the multi-band MR image 1100 (S1210). According to an exemplary embodiment, the multi-band MR image 1100 may be an image obtained by acquiring at least two 2D MR imaging slices of the object at one time.

The MRI apparatus may acquire a multi-band k-space data set 1110 by performing a Fourier transform on the multi-band MR image 1100.

The MRI apparatus acquires k-space data sets 2-1 1121 and 2-2 1122 respectively for a plurality of second MR images 1131 and 1132 by respectively applying weighting coefficients W₁ and W₂ to the acquired multi-band k-space data set 1110 (S1220). According to an exemplary embodiment, the MRI apparatus may acquire the k-space data set 2-1 1121 by multiplying a matrix with the multi-band k-space data set 1110 by the first weighting coefficient matrix W₁ (See FIGS. 9A, 9B, and 10). In the same way, the MRI apparatus may acquire the k-space data set 2-2 1122 by multiplying the matrix with the multi-band k-space data set 1110 by the second weighting coefficient matrix W₂ (See FIGS. 9A, 9B, and 10).

The MRI apparatus reconstructs a plurality of second MR images 2-1 1131 and 2-2 1132 by respectively performing an inverse Fourier transform on the k-space data sets 2-1 1121 and 2-2 1122 for the plurality of second MR images 1131 and 1132 (S1230). According to an exemplary embodiment, the MRI apparatus may reconstruct the second MR image 2-1 1131 by performing an inverse Fourier transform on the k-space data set 2-1 1121. Similarly, the MRI apparatus may reconstruct the second MR image 2-2 1132 by performing an inverse Fourier transform on the k-space data set 2-2 1122.

In an exemplary embodiment, each of the second MR images 2-1 1131 and 2-2 1132 may be a single-band MR image including only one image of the object.

The above-described exemplary embodiments of the present disclosure may be written as computer programs and may be implemented in general-use digital computers that execute the programs using a computer-readable recording medium.

Examples of the computer-readable recording medium include magnetic storage media (e.g., ROM, floppy disks, hard disks, etc.), optical recording media (e.g., CD-ROMs or DVDs), and transmission media such as Internet transmission media.

While the present disclosure has been shown and described with reference to exemplary embodiments thereof, it will be understood by those of ordinary skill in the art that various changes in form and details may be made therein without departing from the spirit and scope of the inventive concept as defined by the following claims. Accordingly, the above exemplary embodiments and all aspects thereof are examples only and are not limiting.

What is claimed is:

1. A method of reconstructing magnetic resonance (MR) images of an object, the method being performed by a magnetic resonance imaging (MRI) apparatus, and the method comprising:
synthesizing first MR images of the object to generate a synthesized first MR image;
acquiring a k-space data set of the synthesized first MR image;
determining a weighting coefficient representing a relationship between the acquired k-space data set and a k-space data set of a respective one of the first MR images, for each of the first MR images;
obtaining a multi-band MR image of the object by applying a multi-band radio frequency signal to the object; and
reconstructing second MR images from the obtained multi-band MR image, based on the determined weighting coefficient for each of the first MR images.

2. The method of claim 1, further comprising:
receiving only some of MR signals that are emitted from the object for a predetermined time;
obtaining the first MR images, based on the received some of the MR signals; and
overlapping at least two of the obtained first MR images in a time domain,
wherein the acquiring of the k-space data set of the synthesized first MR image comprises acquiring the k-space data set of the synthesized first MR image by performing a Fourier transform on the overlapped at least two of the obtained first MR images.

3. The method of claim 2, wherein the first MR images comprise a low resolution MR image having a resolution lower than a resolution of the second MR images.

4. The method of claim 1, further comprising overlapping at least two of the first MR images having different contrasts in a time domain, wherein the acquiring of the k-space data set of the synthesized first MR image comprises acquiring the k-space data set of the synthesized first MR image by performing a Fourier transform on the overlapped at least two of the first MR images.

5. The method of claim 4, wherein the first MR images comprise an MR image that is obtained using an MR imaging protocol that is the same as an MR imaging protocol that is used to obtain the second MR images, and the MR image has a contrast different than a contrast of the second MR images.

6. The method of claim 1, wherein the acquiring of the k-space data set of the synthesized first MR image comprises acquiring the k-space data set of the synthesized first MR image via channel coils,
the method further comprises:
constructing a matrix containing pieces of the acquired k-space data of the synthesized first MR image;
determining an inverse matrix of the constructed matrix; and
acquiring the k-space data set of each of the first MR images via the channel coils, and
the determining of the weighting coefficient for each of the first MR images comprises determining the weighting coefficient for each of the first MR images by multiplying the determined inverse matrix by a matrix containing the acquired k-space data set of the respective one of the first MR images.

7. The method of claim 1, further comprising:
acquiring a k-space data set of the multi-band MR image; and
acquiring a k-space data set of each of the second MR images by applying a respective one of weighting coefficients to the acquired k-space data set of the multi-band MR image,
wherein the reconstructing of the second MR images comprises reconstructing the second MR images by performing an inverse Fourier transform on the acquired k-space data set of each of the second MR images.

8. The method of claim 1, wherein each of the second MR images is a single-band MR image comprising only one MR image of the object.

9. A non-transitory computer-readable storage medium storing a program to cause a computer to perform the method of claim 1.

10. A magnetic resonance imaging (MRI) apparatus for reconstructing magnetic resonance (MR) images of an object, the MRI apparatus comprising:
a radio frequency (RF) receiver configured to receive MR signals that are emitted from the object; and
an image processor configured to:
obtain first MR images of the object, based on the received MR signals;
synthesize the obtained first MR images to generate a synthesized first MR image;
acquire a k-space data set of the synthesized first MR image;
determine a weighting coefficient representing a relationship between the acquired k-space data set and a k-space data set of a respective one of the obtained first MR images, for each of the obtained first MR images;
obtain a multi-band MR image of the object by controlling to apply a multi-band radio frequency signal to the object; and
reconstruct second MR images from the obtained multi-band MR image, based on the determined weighting coefficient for each of the obtained first MR images.

11. The MRI apparatus of claim 10, wherein the RF receiver is further configured to receive only some of MR signals that are emitted from the object for a predetermined time, and
the image processor is further configured to:
obtain the first MR images, based on the received some of the MR signals;
overlap at least two of the obtained first MR images in a time domain; and
acquire the k-space data set of the synthesized first MR image by performing a Fourier transform on the overlapped at least two of the obtained first MR images.

12. The MRI apparatus of claim 11, wherein the first MR images comprise a low resolution MR image having a resolution lower than a resolution of the second MR images.

13. The MRI apparatus of claim 10, wherein the image processor is further configured to:
overlap at least two of the first MR images having different contrasts in a time domain; and
acquire the k-space data set of the synthesized first MR image by performing a Fourier transform on the overlapped at least two of the first MR images.

14. The MRI apparatus of claim 13, wherein the first MR images comprise an MR image that is obtained using an MR imaging protocol that is the same as an MR imaging protocol that is used to obtain the second MR images, and
the MR image has a contrast different than a contrast of the second MR images.

15. The MRI apparatus of claim 10, wherein the image processor is further configured to:
acquire the k-space data set of the synthesized first MR image via channel coils;
construct a matrix containing pieces of the acquired k-space data of the synthesized first MR image;
determine an inverse matrix of the constructed matrix;
acquire the k-space data set of each of the first MR images via the channel coils; and
determine the weighting coefficient for each of the first MR images by multiplying the determined inverse matrix by a matrix containing the acquired k-space data set of the respective one of the first MR images.

16. The MRI apparatus of claim 10, wherein the image processor is further configured to:
acquire a k-space data set of the multi-band MR image;
acquire a k-space data set of each of the second MR images by applying a respective one of weighting coefficients to the acquired k-space data set of the multi-band MR image; and
reconstruct the second MR images by performing an inverse Fourier transform on the acquired k-space data set of each of the second MR images.

17. The MRI apparatus of claim 10, wherein each of the second MR images is a single-band MR image comprising only one MR image of the object.
